(19) United States
(12) Patent Application Publication
(10) Pub. No.: US 2026/0028750 A1
(43) Pub. Date: Jan. 29, 2026

(54) DISRUPTIVE FLOW PROTRUSIONS TO ADJUST FLOW, AND RELATED CHAMBER KITS, METHODS, AND PROCESSING CHAMBERS

(71) Applicant: Applied Materials, Inc., Santa Clara, CA (US)

(72) Inventors: Yi-Chiau HUANG, Fremont, CA (US); Mengjing WANG, Sunnyvale, CA (US); Toi Yue Becky LEUNG, San Jose, CA (US); Zuoming ZHU, Sunnyvale, CA (US)

(21) Appl. No.: 18/783,978

(22) Filed: Jul. 25, 2024

(51) Int. Cl. C30B 25/14; C30B 25/12

(52) U.S. Cl. CPC C30B 25/14; C30B 25/12

(57) ABSTRACT

The present disclosure relates to semiconductor processing chambers, and more particularly, to disruptive flow protrusions to adjust gas flow. In one or more embodiments, a processing chamber includes a substrate support, a plate above the substrate support, one or more gas inlets to provide gas that flows across a gas flow path between the plate and the substrate support, and one or more protrusions extending from the plate towards the substrate support into the gas flow path to disrupt a flow of the gas in the gas flow path.

### BACKGROUND

### Field

The present disclosure relates to semiconductor processing chambers, and more particularly, to disruptive flow protrusions to adjust gas flow.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface.

However, gas flow can be limited with respect to adjustability and residence time, which can negatively affect deposition uniformity, element concentration, and/or performance of the manufactured device. For example, laminar flow can facilitate growth rate selectivity but can be limited with respect to element (such as dopant) concentration. It can also be difficult to activate gases for deposition. Rotation of the substrate, if used, can exacerbate adjustment difficulties. Relatively low rotation speeds, high pressures, and/or low flow rates can also exacerbate adjustment difficulties.

Therefore, a need exists for improved process chamber components.

### SUMMARY

The present disclosure relates to semiconductor processing chambers, and more particularly, to disruptive flow protrusions to adjust gas flow.

In one or more embodiments, a processing chamber includes a substrate support, a plate above the substrate support, one or more gas inlets to provide gas that flows across a gas flow path between the plate and the substrate support. The processing chamber includes one or more protrusions extending from the plate towards the substrate support into the gas flow path to disrupt a flow of the gas in the gas flow path.

In one or more embodiments, a plate apparatus applicable for a processing chamber includes a plate and a plurality of protrusions extending relative to an outer face of the plate. The plurality of protrusions are arranged in a plurality of sets spaced from each other along the outer face. The plurality of sets respectively include at least one of the protrusions arranged along a geometric pattern.

In one or more embodiments, a method of substrate processing includes heating a substrate support in a processing volume, and flowing one or more process gases along a gas flow path between the substrate support and a plate spaced from the substrate support. The method includes disrupting, with the one or more protrusions extending from the plate into the gas flow path, a flow of the gas in the gas flow path.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic side cross-sectional view of a processing chamber, according to one or more embodiments.

FIG. 2 is an enlarged side view of the plate and the protrusions coupled to the plate shown in FIG. 1, according to one or more embodiments.

FIG. 3 is a schematic bottom view of the plate and the protrusions shown in FIGS. 1 and 2, according to one or more embodiments.

FIG. 4 is a schematic bottom view of the plate and the protrusions shown in FIGS. 1 and 2, according to one or more embodiments.

FIG. 5 is a schematic bottom view of the plate and the protrusions shown in FIG. 4, according to one or more embodiments.

FIGS. 6A and 6B are partial schematic side views of adjusting a spacing between the plate and the substrate, according to one or more embodiments.

FIG. 7 is a schematic partial perspective view of the chamber kit, according to one or more embodiments.

FIG. 8A is a schematic partial perspective view of the liner and blocks of the chamber kit, according to one or more embodiments.

FIG. 8B is a schematic partial perspective view of the isolation plate of the chamber kit, according to one or more embodiments.

FIG. 8C is a schematic partial perspective view of the isolation plate and the liner of the chamber kit, according to one or more embodiments.

FIG. 9 is a schematic block diagram view of a method of substrate processing for semiconductor manufacturing, according to one or more embodiments.

FIG. 10 is a partial schematic side cross-sectional view of a processing chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to semiconductor processing chambers, and more particularly, to disruptive flow protrusions to adjust gas flow.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

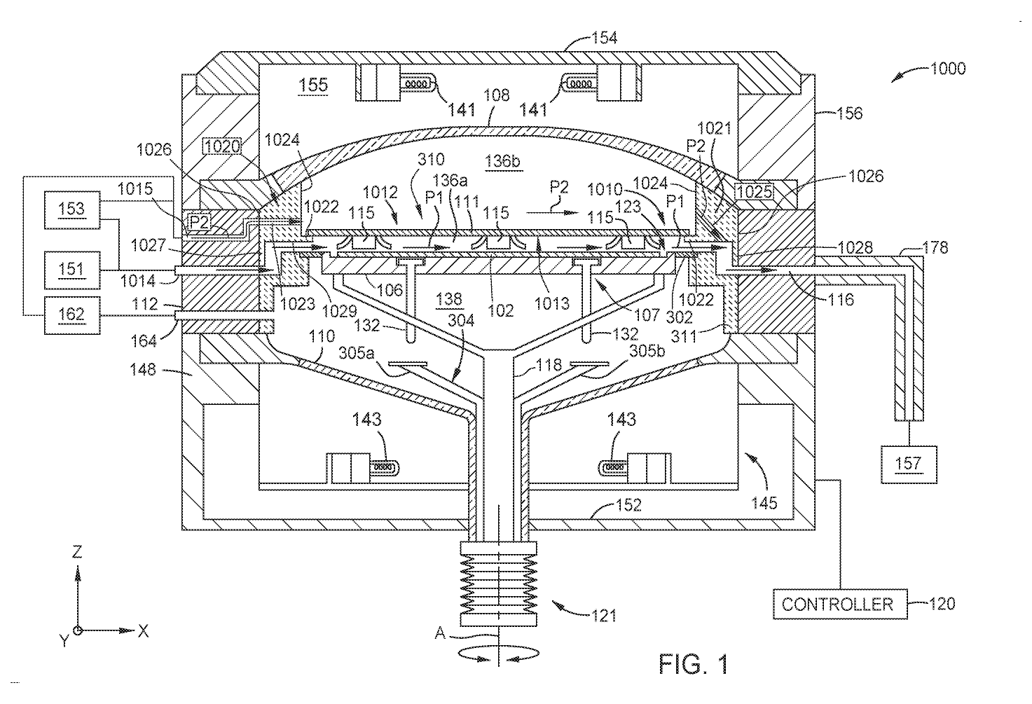

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper plate 108 (such as an upper window and/or an upper dome), a lower plate 110 (such as a lower window and/or a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper plate 108 and the lower plate 110. The substrate support 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 100. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. The pre-heat ring 302 is supported on a ledge of the lower liner 311. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

A chamber kit 1010 includes an isolation plate 111 having a first outer face 1012 and a second outer face 1013 opposing the first outer face 1012. The second outer face 1013 faces the substrate support 106. The chamber body includes an upper liner 1020 and the lower liner 311. The upper liner 1020 includes an annular section 1021. The upper liner 1020 includes one or more inlet openings 1023 extending to an inner surface 1024 of the annular section 1021 on a first side of the upper liner 1020, and one or more outlet openings 1025 extending to the inner surface 1024 of the annular section 1021 on a second side of the upper liner 1020.

The one or more inlet openings 1023 extend from an outer surface 1026 of the annular section 1021 of the upper liner 1020 to the inner surface 1024. The one or more outlet openings 1025 extend from a lower surface 1029 of the upper liner 1020 to the inner surface 1024. The upper liner 1020 includes a first extension 1027 and a second extension 1028 disposed outwardly of the lower surface 1029 of the upper liner 1020. At least part of the annular section 1021 of the upper liner 1020 is aligned with the first extension 1027 and the second extension 1028. In the embodiment shown in FIG. 1, a lowermost end of the isolation plate 111 is aligned above a lowermost end of the upper liner 1020. In one or more embodiments, as shown in FIG. 1, the lowermost end of the isolation plate 111 is part of the second outer face 1013, and the lowermost end of the upper liner 1020 is part of the first extension 1027 and/or the second extension 1028. The present disclosure contemplates that the lowermost end of the upper liner 1020 can be part of the lower surface 1029.

The isolation plate 111 is in the shape of a disc, and the annular section 1021 is in the shape of a ring. It is contemplated, however, that the isolation plate 111 and/or the annular section 1021 can be in the shape of a rectangle, or other geometric shapes. The isolation plate 111 at least partially fluidly isolates an upper portion 136b of an internal volume from a lower portion 136a of the internal volume. The lower portion 136a is a processing volume. The isolation plate 111 at least partially defines the processing volume between the plate 111 and the substrate support 106.

The flow module 112 (which can define at least part of one or more sidewalls of the processing chamber 1000) includes one or more first inlet openings 1014 (e.g., one or more gas inlets) in fluid communication with the lower portion 136a (e.g., the processing volume) of the internal volume. The flow module 112 includes one or more second inlet openings 1015 (e.g., one or more second gas inlets) in fluid communication with the upper portion 136b of the internal volume. The one or more first inlet openings 1014 are in fluid communication with one or more flow gaps between the upper liner 1020 and the lower liner 311. The one or more second inlet openings 1015 are in fluid communication with the one or more inlet openings 1023 of the upper liner 1020. The first inlet openings 1014 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one or more embodiments, the one or more process gases include silicon hydrides (such as one or more silanes and/or one or more chlorinated silanes) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

In one or more embodiments, as shown in FIG. 1, the one or more inlet openings 1023 are oriented in a horizontal orientation and the one or more outlet openings 1025 are oriented in an angled orientation. The present disclosure contemplates that the one or more inlet and/or outlet openings 1023, 1025 can be oriented in a horizontal orientation, oriented in an angled (e.g., non-parallel to horizontal) orientation, and/or can include one or more turns (such as the turns shown for the one or more first inlet openings 1014 and the one or more gas exhaust outlets 116).

During a deposition operation (e.g., an epitaxial growth operation), the one or more process gases P1 flow through the one or more first inlet openings 1014, through the one or more gaps, and into the lower portion 136a to flow over the substrate 102 in a gas flow path between the plate 111 and the substrate support 106. During the deposition operation, one or more purge gases P2 flow through the one or more second inlet openings 1015, through the one or more inlet openings 1023 of the upper liner 1020, and into the upper portion 136b. The one or more purge gases P2 flow simultaneously with the flowing of the one or more process gases P1. The flowing of the one or more purge gases P2 through the upper portion 136b facilitates reducing or preventing flow of the one or more process gases P1 into the upper portion 136b that would contaminate the upper portion 136b. The one or more process gases P1 are exhausted through gaps between the upper liner 1020 and the lower liner 311, and through the one or more gas exhaust outlets 116. The one or more purge gases P2 are exhausted through the one or more outlet openings 1025, through the same gaps between the upper liner 1020 and the lower liner 311, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116. The one or more process gases P1 can include a deposition precursor, a carrier gas, an etchant gas, a cleaning gas, and/or a mixture thereof, for example.

The present disclosure also contemplates that one or more purge gases can be supplied to the purge volume 138 (through the plurality of purge gas inlets 164) during the deposition operation, and exhausted from the purge volume 138.

A plate apparatus includes the plate 111 and one or more protrusions 115 extending relative to the second outer face 1013 of the plate 111. In one or more embodiments, the one or more protrusions 115 includes a plurality of protrusions 115. The protrusions 115 extend toward the substrate 102 and the substrate support 106. The protrusions 115 are disruptive features that extend into the gas flow path between the substrate support 106 and the plate 111 to disrupt the flow of the process gases P1 between the plate 111 and the substrate 102. For example, the protrusions 115 can adjust a flow pattern (such as to induce a swirl (e.g., a vortex), an eddy, and/or a turbulence) for the process gases P1. Other forms of flow patterns are contemplated. In one or more embodiments, the protrusions 115 are fins. The protrusions 115 are coupled to the plate 111. As an example, the protrusions 115 can be integrally formed with the plate 111. As another example, the protrusions 115 can be welded or fused to the plate 111. The protrusions 115 and/or at least part of the plate 111 are formed of a transparent material. In one or more embodiments, the transparent material includes quartz (e.g., transparent quartz). In one or more embodiments, at least part of the plate 111 is formed of the transparent material, and the protrusions 115 are formed of an opaque material (such as opaque quartz (e.g. white quartz, or grey quartz; and/or black quartz), silicon carbide (SiC), graphite coated with SiC, and/or one or more ceramics (such as alumina (aluminum oxide (Al2O3)), aluminum nitride (AlN), silicon nitride (Si3N4), Boron Nitride (BN), and/or Boron Carbide (B4C))). In one or more embodiments, the protrusions 115 and at least part of the plate 111 are formed of the opaque material. The transparent material can facilitate the heating energy from the 141 to pass therethrough and to the substrate support 106 and/or the substrate 102. The opaque material can adjust (e.g., modulate) localized heat transfer of localized heating.

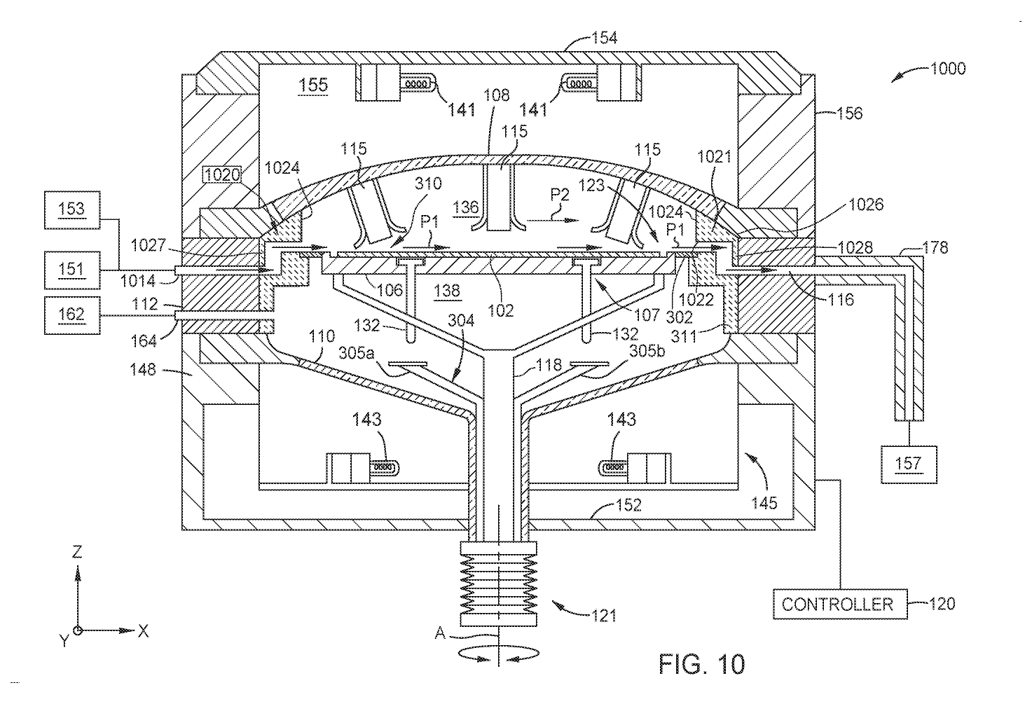

The present disclosure contemplates that other parts of the processing chamber 1000 can include the protrusions 115. For example, as shown in FIG. 10 (described below) the upper plate 108 (e.g., the upper window and/or the upper dome) can include the protrusions 115.

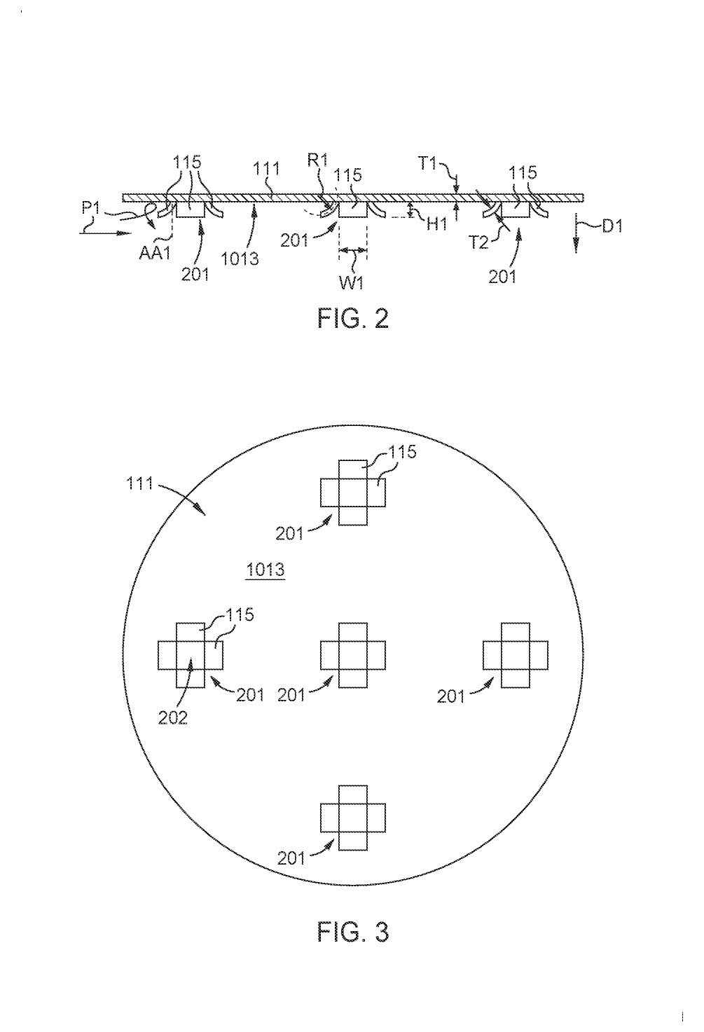

FIG. 2 is an enlarged side view of the plate 111 and the protrusions 115 coupled to the plate 111 shown in FIG. 1, according to one or more embodiments.

The protrusions 115 can be curved (such as in the shape of a winglet), as shown in FIG. 2. The present disclosure contemplates other orientations for the protrusions 115. For example, the protrusions 115 can be linear and/or can include sections that intersect each other at an angle. The plurality of protrusions 115 are arranged in a plurality of sets 201 spaced from each other along the second outer face 1013. Three of the sets 201 are shown in FIG. 2 and five of the sets 201 are shown in FIG. 3.

The plate 111 has a first thickness T1. In one or more embodiments, the first thickness T1 is within a range of 3.0 mm to 5.0 mm, such as within a range of 4.0 mm to 5.0 mm. In one or more embodiments, at least one (such as one, some, or all) of the protrusions 115 have a second thickness T2 within a range of 0.1 mm to 4.0mm, such as 1.0 mm to 4.0 mm. In one or more embodiments, the second thickness T2 is within a range of 2.0 mm to 3.0 mm. In one or more embodiments, the first thickness T1 is larger than the second thickness T2 of at least one (such as one, some, or all) of the protrusions 115. At least part of at least one (such as one, some, or all) of the plurality of protrusions 115 diverges from an axis AA1 extending perpendicularly from the plate 111. For example, the protrusion(s) 115 can slant or curve away from the axis AA1. As another example, the protrusion(s) 115 can include a linear section extending along the axis AA1 and a diverging section that is curved, slanted, and/or extending perpendicularly relative to the linear section. At least one (such as one, some, or all) of the plurality of protrusions 115 has a width W1 larger than a height H1. The at least one of the plurality of protrusions 115 is curved and has a radius of curvature R1. The radius of curvature R1 is less than the width W1 and less than the height H1. The width W1 is greater than 4.0 mm, such as 5.0 mm or higher. In one or more embodiments, the width W1 is less than 100 mm, such as less than 50 mm, for example, less than 20 mm. In one or more embodiments, the width W1 is 15 mm or less, such as 10 mm or less. In one or more embodiments, at least one (such as one, some, or all) of the plurality of protrusions 115 have the width W1 along a direction perpendicular to the gas flow path for the one or more process gases P1 (e.g., a direction extending into the page in FIG. 1).

As an example, the flow of the one or more process gases P1 can flow against the protrusions 115 to turn over on itself (as shown in FIG. 2) to adjust the flow pattern of the one or more process gases P1.

FIG. 3 is a schematic bottom view of the plate 111 and the protrusions 115 shown in FIGS. 1 and 2, according to one or more embodiments.

The plurality of sets 201 respectively include at least one (such as one, some, or all) of the protrusions 115 arranged along a geometric pattern 202. In one or more embodiments, the plurality of sets 201 respectively include a group of the protrusions 115 arranged along the geometric pattern 202. In one or more embodiments, the geometric pattern is a rectangle. The rectangle can be a square or a rectangle having sides with unequal lengths. In one or more embodiments, the plurality of sets 201 respectively include protrusions 115 disposed about sides of the rectangle. In one or more embodiments, the sets 201 respectively include four protrusions 115. The protrusions 115 of the respective sets 201 curve outwardly away from the geometric pattern 202 in a direction D1 (FIG. 2) away from the second outer face 1013.

At least one (such as one, some, or all) set 201 of protrusions 115 is angularly aligned with at least one other set 201 of protrusions 115. FIG. 3 shows all the sets 201 of protrusions 115 angularly aligned with each other relative to central axes through the geometric pattern of respective sets 201.

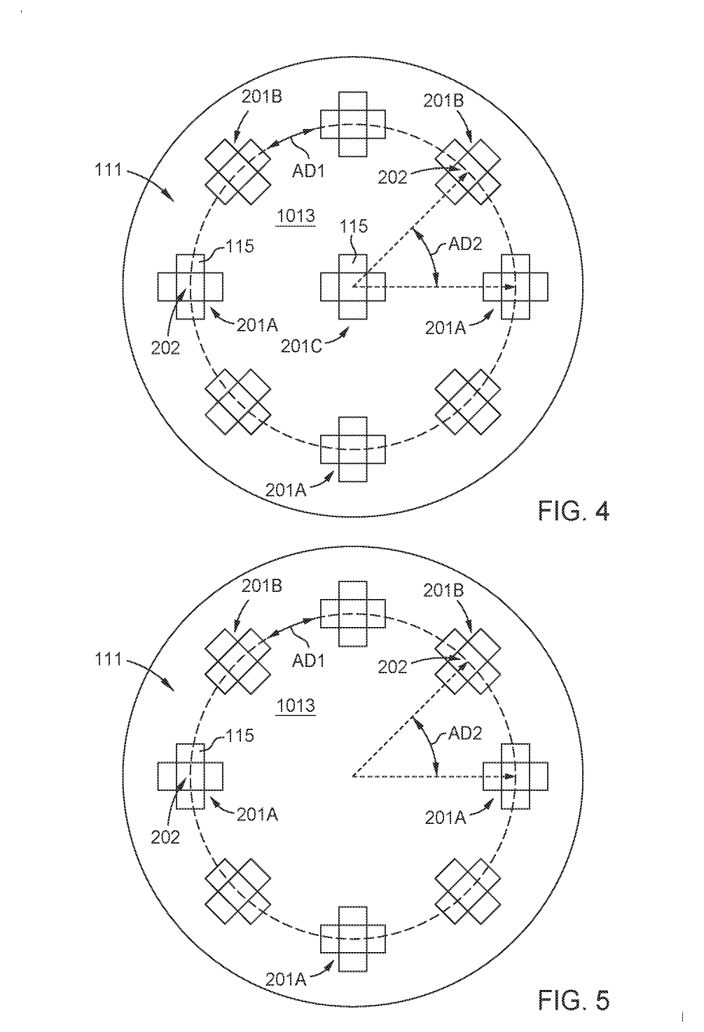

FIG. 4 is a schematic bottom view of the plate 111 and the protrusions 115 shown in FIGS. 1 and 2, according to one or more embodiments.

In the implementation shown in FIG. 4, some of the sets 201A of protrusions 115 are angularly aligned with each other. At least one (such as one, some, or all) set 201B of protrusions 115 is angularly offset from the at least one (shown as some in FIG. 4) other set 201A of protrusions 115. FIG. 4 shows sets 201B of protrusions 115 angularly offset from sets 201A of protrusions 115 by an angle of about 45 degrees. In one or more embodiments, an inner set 201C of the plurality of sets 201 is centrally disposed along the second outer face 1013, and one or more outer sets 201A, 201B of the plurality of sets 201 are disposed radially outward of the inner set 201C. The sets 201A-201C of protrusions 115 are uniformly distributed across the second outer face 1013 of the plate 111. In one or more embodiments, the one or more outer sets 201A, 201B include a plurality of outer sets 201A, 201B distributed substantially uniformly from each other with respect to an azimuthal direction AD1. In such an embodiment, a maximum azimuthal difference AD2 between adjacent outer sets 201A, 201B is within a difference of 10% or less of a minimum azimuthal difference Ad2 between adjacent outer sets 201A, 201B.

FIG. 5 is a schematic bottom view of the plate 111 and the protrusions 115 shown in FIG. 4, according to one or more embodiments.

In the implementation shown in FIG. 5, the inner set 201C of protrusions 115 is omitted. The inner set 201C can be omitted, for example, when a flow pattern disruption (such as swirl (e.g., vortex) and/or turbulence) occurs over a central zone of the substrate 102. The outer sets 201A, 201B can be used to induce a flow pattern disruption over an outer zone (such as an edge zone) of the substrate 102 to more uniformly generate a flow pattern over the substrate 102. A rotation of the substrate 102 (e.g., using the substrate support 106) can facilitate generation of the flow pattern disruption.

The present disclosure contemplates that the dimensions, shapes, and/or distributions of the protrusions 115 can be equal to each other or can vary. For example, the height H1, width W1, the thickness T2, and/or the shape of the protrusions 115 of the inner set 201C can be different than the protrusions 115 of the outer sets 201A, 201B. As another example, the distribution of one or more sets of protrusions 115 corresponding to a respective zone of the substrate 102 can be equal within for the respective zone.

The present disclosure contemplates that the positions of the protrusions 115 can vary relative to the positions shown in FIGS. 1-6B. The numbers of protrusions 115 can vary.

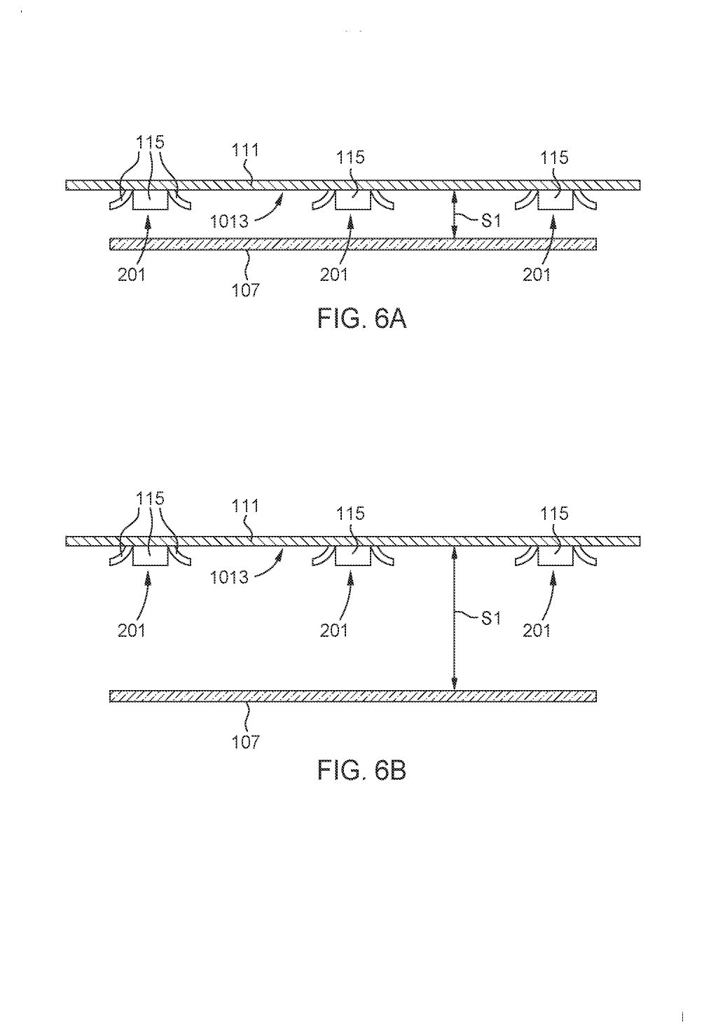

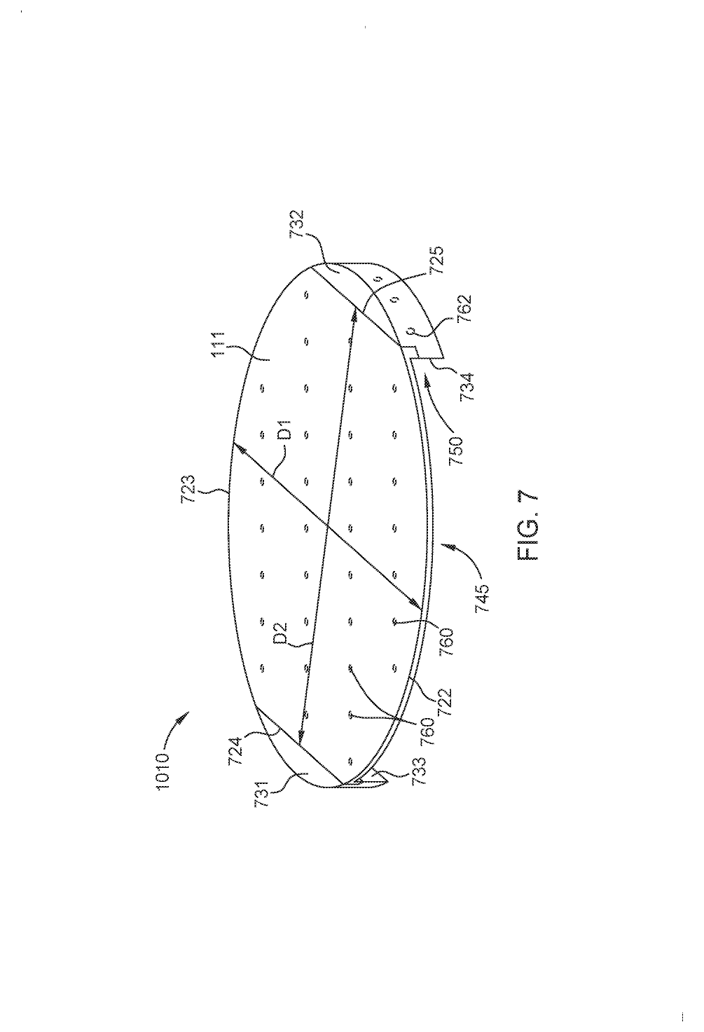

FIGS. 6A and 6B are partial schematic side views of adjusting a spacing S1 between the plate 111 and the substrate 102, according to one or more embodiments. Using raising and lowering of the substrate support 106, a spacing S1 between the plate 111 and the substrate 102 can be adjusted. FIG. 6B shows the spacing S1 as increased relative to FIG. 6A. The present disclosure contemplates that FIG. 6A (e.g., a smaller spacing S1) can be used for enhanced flow pattern disruptions, longer residence time of gases (such as reactive gases, for example the one or more process gases P1), less smooth boundary layers, and/or increased heat transfer to the substrate 102. The present disclosure contemplates that FIG. 6B (e.g., a larger spacing S1) can be used for more laminar flow, shorter residence time of gases (such as reactive gases, for example the one or more process gases P1), smooth boundary layers, and/or decreased heat transfer to the substrate 102. Processing methods can involve various values for the spacing S1, such as at various operations of the processing methods. For example, high pressure deposition of layers including silicon and phosphorus (e.g., SiP layers) can involve deposition at FIG. 6B and then deposition at FIG. 6A for higher phosphorus concentration. The spacing S1 can be reduced to induce a flow pattern disruption and/or the spacing S1 can be increased to reduce the flow pattern disruption. The induced flow pattern disruption can be an increase in swirl (e.g., vortex), edd(ies), and/or turbulence.

FIG. 7 is a schematic partial perspective view of the chamber kit 1010, according to one or more embodiments. A first block 731 and a second block 732 are disposed opposite to one another, on opposing sides of the plate 111. The plate 111 and the two blocks 731, 732 together are part of a flow guide insert that has a circular shape, and other geometric configurations are contemplated.

The isolation plate 111 includes a first side 722 and a second side 723 opposing the first side 722 along a first direction D1. Each of the first side 722 and the second side 723 is arcuate. In one or more embodiments, the direction D1 is parallel to the direction of gas flow in the processing chamber 1000 of FIG. 1 in order to guide process gas P1 within the rectangular flow opening 750 defined between a planar inner surface 733 of the first block 731 and a planar inner surface 734 of the second block 732.

The first block 731 extends outwardly from and couples to a third side 724 of the isolation plate 111, and the second block 732 extends outwardly from and couples to a fourth side 725 of the isolation plate 111. The third side 724 is opposite the fourth side 725 along a direction D2, which is perpendicular to direction D1. The third side 724 and the fourth side 725 are linear, as are surfaces of the first block 731 and the second block 732 which mate with the third side 724 and the fourth side 725 of the isolation plate 111.

It is contemplated that the first block 731 and the second block 732 may be omitted from the flow guide insert (as shown in FIG. 1). In one or more embodiments where the blocks 731 and 732 are omitted, the isolation plate 111 can be supported by the upper liner 1020 and/or the isolation plate 111 may be secured in the interior of the processing chamber via another attachment mechanism. It is contemplated that the first and second blocks 731, 732 may include actuating supports configured to mechanically move the isolation plate 111 up and down. During processing, one or more process gases (such as process gas P1 of FIG. 1) flow through the rectangular flow opening 750 when flowing through the lower portion 136a and over the substrate 102.

As shown in FIG. 7, the isolation plate 111 can include a plurality of openings 760 (e.g., perforations) formed therethrough, and/or the blocks 731, 732 can include a plurality of openings 762 (e.g., perforations). It is to be noted that while openings 762 are only shown in the second parallel block 732 in FIG. 7 for clarity, openings 762 are also formed in the first block 731.

The openings 760 and/or the openings 762 can be omitted (as shown in FIG. 1) from the isolation plate 111, the first block 731, and/or the second block 732.

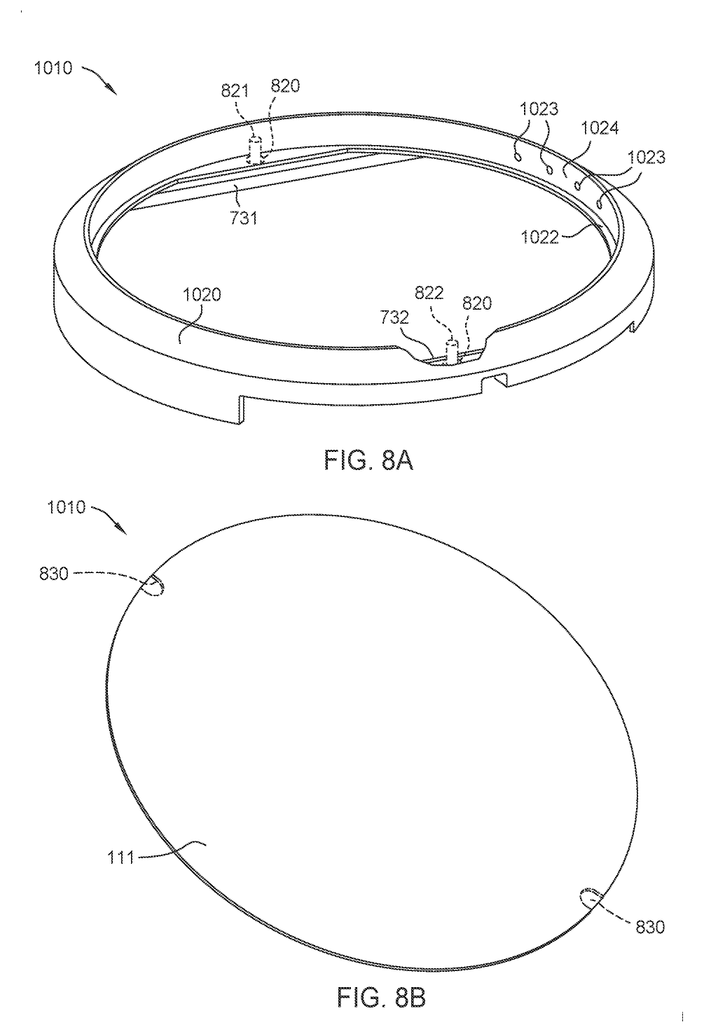

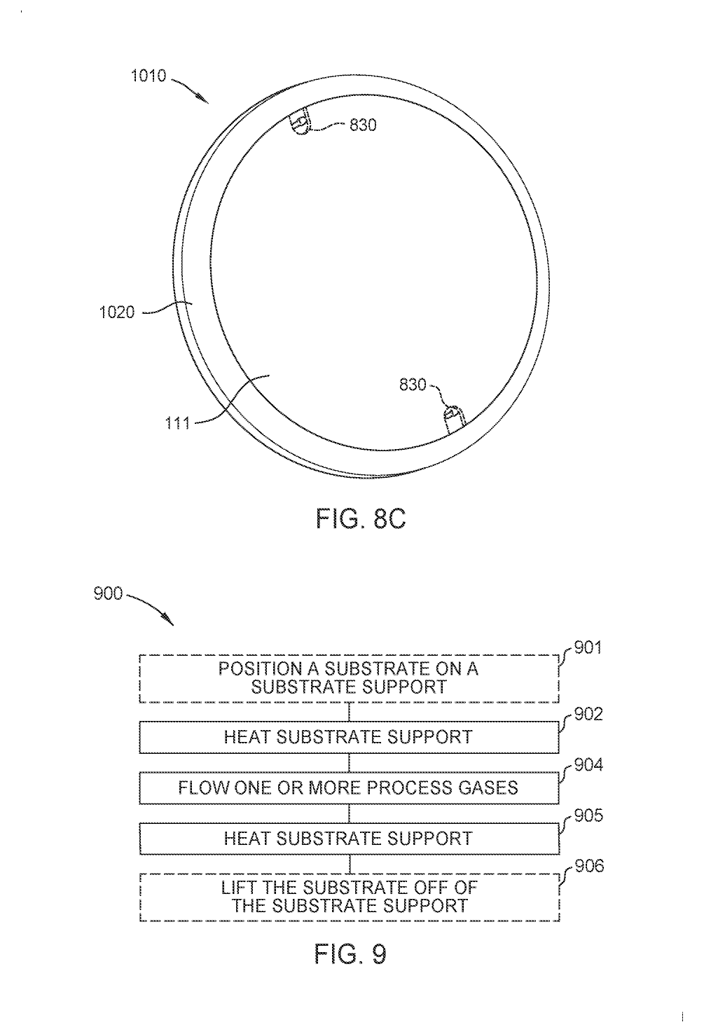

FIG. 8A is a schematic partial perspective view of the liner 1020 and blocks 731, 732 of the chamber kit 1010, according to one or more embodiments. In the implementation shown in FIG. 8A, the blocks 731, 732 are coupled to the liner 1020. In one or more embodiments, the blocks 731, 732 and the liner 1020 are manufactured together as a single integral part of the processing chamber 1000 such that the blocks 731, 732 and the liner 1020 are part of the same opaque body. In one or more embodiments, the blocks 731, 732 are manufactured as separate bodies from the liner 1020, and the blocks 731, 732 are fused to the liner 1020 in a fusing operation. In one or more embodiments, the blocks 731, 732 are welded to the liner 1020.

As shown in FIG. 8A, in one or more embodiments, the blocks 731, 732 includes optional slots 820. It is contemplated that the slots 820 may be omitted from the blocks 731, 732. The blocks 731, 732 respectively include one or more alignment extensions 821, 822 extending relative to the respective block 731, 732. The alignment extensions 821, 822 can include, for example, columns (such as cylindrical rods and/or rectangular rods). The one or more alignment extensions 821, 822 can be omitted.

FIG. 8B is a schematic partial perspective view of the isolation plate 111 of the chamber kit 1010, according to one or more embodiments. In one or more embodiments, the isolation plate 111 includes notches 830. It is contemplated that the notches 830 may be omitted from the isolation plate 111. In one or more embodiments, the notches 830 of the isolation plate 111 and the slots 820 of the blocks 731, 732 are used to position the isolation plate 111 on the blocks 731, 732 and one or more inner ledges 1022 of the liner 1020. For example, transfer equipment (such as heads of lift pins) can extend through the notches 830 and into slots 820 when the isolation plate 111 is lowered onto the upper liner 1020. The lift pins can be part of the alignment extensions, and the alignment extensions 821, 822 can be movable relative to the blocks 731, 732. The alignment extensions 821, 822 can be coupled to the blocks 731, 732, and the alignment extensions 821 822 can extend through the notches 830 to align the isolation plate 111 relative to the blocks 731, 732.

FIG. 8C is a schematic partial perspective view of the isolation plate 111 and the liner 1020 of the chamber kit 1010, according to one or more embodiments. In one or more embodiments, the notches 830 and/or the alignment extensions 821, 822 vertically align with the slots 820 when the isolation plate 111 is positioned on the blocks 731, 732 and/or the one or more inner ledges 1022, and/or when the isolation plate 111 is fused to the blocks 731, 732 and/or the one or more inner ledges 1022. In one or more embodiments, the isolation plate 111 is fused to the blocks 731, 732 and/or the one or more inner ledges 1022. In one or more embodiments, the blocks 731, 732 and/or the one or more inner ledges 1022 are welded to the isolation plate 111. The liner 1020 can be formed of the same material as the blocks 731, 732 and/or the isolation plate 111.

FIG. 9 is a schematic block diagram view of a method 900 of substrate processing for semiconductor manufacturing, according to one or more embodiments.

Optional operation 901 includes positioning a substrate on a substrate support in a processing volume of a processing chamber. In one or more embodiments, the positioning includes moving a substrate support and/or a plurality of lift pins relative to each other to land the substrate on the substrate support.

Operation 902 of the method 900 includes heating the substrate support and/or the substrate in the processing volume to a target temperature.

Operation 904 includes flowing one or more process gases between the substrate support and a plate (such as the plate 111 or the upper plate 108) spaced from the substrate support. The one or more process gases flow over the substrate to form one or more layers on the substrate. In one or more embodiments, the one or more process gases flow past the protrusions 115.

Operation 905 includes adjusting a spacing between the substrate support and the plate to adjust a flow pattern of the one or more process gases. The flow pattern can be made less laminar or more laminar.

Optional operation 906 includes lifting the substrate off of the substrate support. In one or more embodiments, the lifting includes moving a substrate support and/or a plurality of lift pins relative to each other to engage the substrate with the lift pins and lift the substrate.

FIG. 10 is a partial schematic side cross-sectional view of a processing chamber 1100, according to one or more embodiments. The processing chamber 1100 includes one or more aspects, features, components, operations and/or properties of the processing chamber 1000 shown in FIG. 1.

The protrusions 115 are coupled to the upper plate 108. The protrusions 115 extend into a gas flow path for the one or more process gases P1 in a processing volume 136 between the plate 111 and the substrate support 106. The protrusions 115 shown in FIG. 10 are longer than the protrusions 115 shown in FIG. 1 to extend into the gas flow path. In the implementation shown in FIG. 10, the plate 111 and the protrusions 115 coupled thereto are omitted such that the one or more process gases P1 flow between the upper plate 108 and the substrate 102. In such an example, at least some of the protrusions 115 coupled to the upper plate 108 can be tilted (as shown in FIG. 1) due to the curvature of the upper plate 108. The protrusions 115 coupled to the upper plate 108 can be level, for example oriented horizontally (as shown in FIG. 1 for the protrusions 115 coupled to the plate 111).

Benefits of the present disclosure include adjustability of gas flow (such as adjustability of flow patterns (e.g., swirl (e.g., vortex), edd(ies), turbulence, and/or and laminar parameters of flow)); adjustability of gas flow patterns and velocities; adjustability of gas residence times; adjustability for high pressure operations; adjustability of element (e.g., dopant) concentrations; adjustability of heat transfer; reduced diversive flow of process gases; enhanced deposition thicknesses; enhanced deposition uniformities; enhanced thermal uniformities; enhanced gas flow rate uniformities; and increased throughput and efficiency; and reduced chamber downtime. As an example, laminar flow can be used for enhanced deposition uniformity, and increased swirl can be used for increased element (e.g., phosphorus) concentration while maintaining growth selectivity. As another example, chamber components can cause swirling at certain areas, and induced swirling can be used to make swirling more uniform across substrates.

Benefits of the present disclosure also include enhanced gas activation (e.g., pre-activation) while reducing or eliminating blockage of radiation that heats the substrate; increased film thickness and growth rates; and adjustability of process parameters (e.g., gas flow rates, temperature, and deposition thickness).

It is contemplated that one or more aspects disclosed herein may be combined. As an example, one or more aspects, features, components, operations and/or properties of the processing chamber 1000, the chamber kit 1010, the plate 111, the protrusions 115, the blocks 731, 732, the one or more alignment extensions 821, 822, the notches 830, the method 900, and/or the processing chamber 1100 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

1. A processing chamber, comprising:
a substrate support;
a plate above the substrate support;
one or more gas inlets to provide gas that flows across a gas flow path between the plate and the substrate support;
one or more protrusions extending from the plate towards the substrate support into the gas flow path to disrupt a flow of the gas in the gas flow path.

2. The processing chamber of claim 1, wherein the one or more protrusions include a plurality of protrusions arranged in a plurality of sets spaced from each other along the outer face of the plate.

3. The processing chamber of claim 2, wherein the plurality of sets respectively include some of the protrusions arranged along a geometric pattern.

4. The processing chamber of claim 3, wherein at least one set of protrusions is angularly aligned with at least one other set of protrusions.

5. The processing chamber of claim 3, wherein the geometric pattern is a rectangle, and the plurality of sets respectively include protrusions disposed about sides of the rectangle.

6. The processing chamber of claim 1, wherein at least one of the one or more protrusions has a thickness within a range of 1.0 mm to 4.0 mm.

7. The processing chamber of claim 1, wherein at least one of the one or more protrusions has a width larger than a height.

8. The processing chamber of claim 1, wherein at least one of the one or more protrusions has a width along a direction perpendicular to the gas flow path, and the width is greater than 4.0 mm.

9. The processing chamber of claim 1, wherein at least part of at least one of the one or more protrusions diverges from an axis extending perpendicularly from the plate.

10. The processing chamber of claim 9, wherein the at least one of the one or more protrusions is curved and has a radius of curvature that is less than the width and less than the height.

11. A plate apparatus applicable for a substrate processing chamber, the plate apparatus comprising:
a plate; and
a plurality of protrusions extending relative to an outer face of the plate, the plurality of protrusions arranged in a plurality of sets spaced from each other along the outer face, and the plurality of sets respectively including a group of the protrusions arranged along a geometric pattern.

12. The plate apparatus of claim 11, wherein the geometric pattern is a rectangle, and the plurality of sets respectively include protrusions disposed about sides of the rectangle.

13. The plate apparatus of claim 11, wherein the protrusions of the respective sets curve outwardly away from the geometric pattern in a direction away from the outer face.

14. The plate apparatus of claim 9, wherein the plurality of protrusions and at least part of the plate are formed of a transparent material, and the transparent material comprises quartz.

15. The plate apparatus of claim 11, wherein at least one set of protrusions is angularly aligned with at least one other set of protrusions.

16. The plate apparatus of claim 15, wherein at least one set of protrusions is angularly offset from the at least one other set of protrusions.

17. The plate apparatus of claim 11, wherein an inner set of the plurality of sets is centrally disposed along the outer face, and one or more outer sets of the plurality of sets are disposed radially outward of the inner set.

18. The plate apparatus of claim 17, wherein the one or more outer sets comprise a plurality of outer sets distributed substantially uniformly from each other with respect to an azimuthal direction.

19. A method of substrate processing, comprising:
heating a substrate support in a processing volume;
flowing one or more process gases along a gas flow path between the substrate support and a plate spaced from the substrate support; and
disrupting, with the one or more protrusions extending from the plate into the gas flow path, a flow of the gas in the gas flow path.

20. The method of claim 19, further comprising adjusting a spacing between the substrate support and the plate to adjust a flow pattern of the one or more process gases, wherein the spacing is reduced to induce the flow pattern over a plurality of protrusions extending relative to an outer face of the plate and toward the substrate support.
